(19) United States
(12) Patent Application Publication
(10) Pub. No.: US 2016/0004068 A1
(43) Pub. Date: Jan. 7, 2016

(54) MICRO-MIRROR DEVICE AND METHOD FOR DRIVING MIRROR THEREOF

(71) Applicant: Himax Display, Inc., Tainan City (TW)

(72) Inventors: Roland V. Gelder, Cupertino, CA (US); Nan Liu, San Jose, CA (US)

(21) Appl. No.: 14/322,272

(22) Filed: Jul. 2, 2014

(51) Int. Cl. G02B 26/08; B81B 7/00; B81B 5/00

(52) U.S. Cl. CPC G02B 26/0841; B81B 5/00; B81B 7/008; B81B 2201/045

(57) ABSTRACT

A micro-mirror device and a method for driving a mirror thereof are disclosed. The micro-mirror device includes a mirror, a first and a second electrode, a memory, and a controller. The mirror is tiltable about a hinge. The first electrode and the second electrode are disposed on different sides of the hinge. The memory stores a state data indicating a first electrode state for the first electrode and a second electrode state for the second electrode corresponding to the mirror. The controller is operable to receive the state data of the first and second electrodes from the memory, and in response to a crossover operation request, the controller inverts the states of the first and second electrodes. The controller sends a reset signal to the mirror according to the modified states of the first and second electrodes.

### BACKGROUND

1. Technical Field

The disclosure relates generally to a micro-mirror device and a method for driving a mirror thereof.

2. Related Art

With the advancement of display technology, micro-mirror devices are used widely in display apparatuses such as projection systems. In these projection systems, light is projected to correspond to color channels of the image. A micro-mirror device in the projection system displays the pixels of an image by tilting mirrors in the device to project light or to deflect light (display or no display). In general, the amount of time that the mirror plates are turned on and off controls the intensity for a given pixel and a given color.

When voltage is applied to the mirrors in the micro-mirror device, electrostatic force attraction may cause the mirrors to tilt in one direction or another, depending on the voltage provided to the electrodes. The micro-mirror device may reset the mirrors by modifying the voltage applied to the mirrors. To overcome the electrostatic forces on the mirror plate, and thus guarantee a proper mirror plate reset, some micro-mirror devices use a bipolar reset signal. The bipolar reset signal temporarily applies a negative voltage to the mirror plate during reset. However, a bipolar reset signal can have several problems, such as the positive and negative power supplies required to generate a bipolar reset signal, which may be costly. In addition, considerably more power may be required to generate the bipolar reset signal.

### SUMMARY

The disclosure provides a micro-minor device capable of maintaining the same crossover reset and stay voltage changes as the bipolar crossover and stay operations.

The micro-minor device includes a mirror, a first electrode, a second electrode, a memory, and a controller. The minor is tiltable about a hinge. The first electrode and the second electrode are disposed on different sides of the hinge. The memory stores a state data indicating a first electrode state for the first electrode and a second electrode state for the second electrode corresponding to the minor. The controller is operable to receive the state data of the first and second electrodes from the memory, and in response to a crossover operation request, the controller inverts the states of the first and second electrodes by applying the second electrode state to the first electrode and applying the first electrode state to the second electrode. Moreover, the controller sends a reset signal to the minor according to the modified states of the first and second electrodes.

According to an embodiment of the disclosure, the first electrode state is a low state and the second electrode state is a high state.

According to an embodiment of the disclosure, the first electrode state is a high state and the second electrode state is a low state.

According to an embodiment of the disclosure, the controller derives the states of the first and second electrodes from a state of the minor specified in the state data from the memory.

According to an embodiment of the disclosure, the controller further includes a reset signal generator providing the reset signal during a reset of the mirror.

According to an embodiment of the disclosure, the reset signal is a unipolar signal.

According to an embodiment of the disclosure, the reset signal has a periodic voltage.

According to an embodiment of the disclosure, the micro-mirror device further includes a first amplifier coupled between the first electrode and the controller, and a second amplifier coupled between the second electrode and the controller, the first and second amplifiers configured to provide power to the electrodes according to the states of the first and second electrodes.

The disclosure provides a method for driving a mirror of a micro-mirror device, including the following steps. A crossover operation request for a mirror is received. A stored state data is retrieved in response to the crossover operation request, in which the state data indicates a first electrode state for a first electrode and a second electrode state for a second electrode corresponding to the mirror. The states of the two electrodes are inverted by applying the second electrode state to the first electrode and applying the first electrode state to the second electrode. A reset signal is sent to the mirror according to the modified states of the electrodes.

In summary, embodiments of the disclosure provide micro-mirror devices and methods of driving a mirror thereof. By employing unipolar electrode state inversion before mirror reset, the unipolar crossover and stay operations with electrode state inversion are able to maintain the same crossover reset and stay voltage changes as the bipolar crossover and stay operations. Accordingly, negative drive voltages are not required while mirror release degradation in stay operations can be reduced.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic view of a micro-mirror device according to an embodiment of the disclosure.

FIGS. 2 and 3 respectively illustrate a bipolar crossover operation and a bipolar stay operation of a micro-mirror device according to an embodiment of the disclosure.

FIGS. 4 and 5 respectively illustrate a unipolar crossover operation and a unipolar stay operation of a micro-mirror device according to an embodiment of the disclosure.

FIGS. 6 and 7 respectively illustrate a unipolar crossover operation and a unipolar stay operation with 0V pre-release of a micro-mirror device according to an embodiment of the disclosure.

FIGS. 8 and 9 respectively illustrate a unipolar crossover operation and a unipolar stay operation with electrode state inversion of a micro-mirror device according to an embodiment of the disclosure.

FIGS. 10 and 11 respectively illustrate the relationships between voltage and time of the bipolar crossover operation and the bipolar stay operation depicted in FIG. 2 and FIG. 3.

FIGS. 12 and 13 respectively illustrate the relationships between voltage and time of the unipolar crossover operation and the unipolar stay operation depicted in FIG. 4 and FIG. 5.

FIGS. 14 and 15 respectively illustrate the relationships between voltage and time of the unipolar crossover operation and the unipolar stay operation with 0V pre-release depicted in FIG. 6 and FIG. 7.

FIGS. 16 and 17 respectively illustrate the relationships between voltage and time of the unipolar crossover operation and the unipolar stay operation with electrode state inversion depicted in FIG. 8 and FIG. 9.

FIG. 18 is a flow diagram of a method for driving a mirror in a micro-mirror device according to an embodiment of the disclosure.

### DETAILED DESCRIPTION OF DISCLOSED EMBODIMENTS

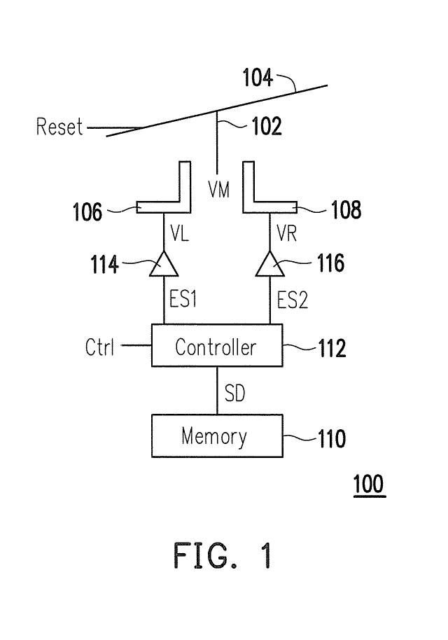

FIG. 1 is a schematic view of a micro-mirror device according to an embodiment of the disclosure. With reference to FIG. 1, in the present embodiment, a micro-mirror device 100 may include a mirror 104, a first electrode 106, a second electrode 108, a memory 110, a controller 112, a first amplifier 114, and a second amplifier 116. The mirror is tiltable about a hinge 102, and the first electrode 106 and the second electrode 108 are disposed on different sides of the hinge 102. In the embodiment, the memory 110 is configured to store a state data SD indicating a first electrode state ES1 for the first electrode 106 and a second electrode state ES2 for the second electrode 108 corresponding to the mirror 104. Moreover, in the present embodiment, the controller 112 is configured to receive the state data SD of the first and second electrodes 106 and 108 from the memory 110.

In the micro-mirror device 100 according to the present embodiment, the state of the first and second electrodes 106 and 108 may be determined from the state data stored in the memory 110. The state of the mirror 104 corresponds to a signal applied to the mirror 104 and the states of the first and second electrodes 106 and 108. Generally, the mirror 104 is tilted toward the first electrode 106 or the second electrode 108 whose voltage potential difference with the mirror 104 is the greatest. A voltage signal VM, for example, may be applied to the mirror 104 by applying the voltage signal VM to a post or other suitable fixtures connected to the hinge 102 and mirror 104. For instance, the voltage signal VM may be transmitted to the mirror 104 through the post shown in FIG. 1.

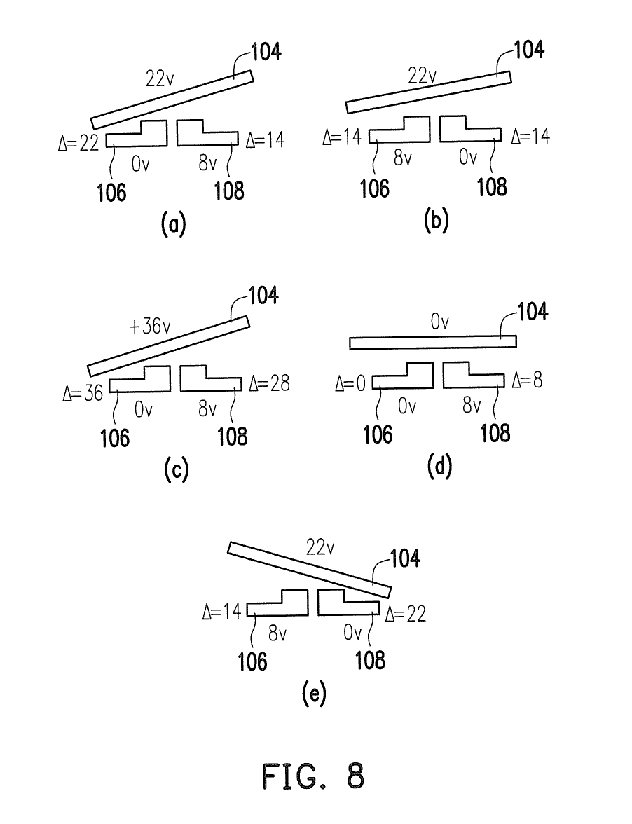

In the micro-mirror device 100 according to the present embodiment, a reset signal RESET may be applied to the mirror 104 to help release the mirror 104 and allow the mirror to crossover (or stay) when appropriate. Furthermore, in some embodiments of the disclosure, in response to a crossover operation request which may be included in a control signal CTRL, the controller 112 may invert the states of the first electrode 106 and the second electrode 108 by applying the second electrode state ES2 to the first electrode 106 and applying the first electrode state ES1 to the second electrode 108, and the controller 112 may send the reset signal RESET to the mirror 104 according to the modified states ES2 and ES1 of the first and second electrodes 106 andstate 108. An implementation of this mirror driving scheme is described with reference to FIG. 8 later in the disclosure. However, in other embodiments of the disclosure, the controller 112 may also maintain the states of the first and second electrodes 106 and 108 before sending the reset signal RESET to the mirror 104.

In some embodiments of the disclosure, the first electrode state ES1 is a low state and the second electrode state ES2 is a high state, while in other embodiments, the first electrode state ES1 is a high state and the second electrode state ES2 is a low state. Electrical signals such as the voltage signals VL and VR may be respectively applied to the first and second electrodes 106 and 108 in response to the electrode states.

In some embodiments of the disclosure, the controller 112 may further include a reset signal generator (not drawn) providing the reset signal RESET during a reset of the mirror 104. However, the reset signal RESET may also be obtained from an external source in other embodiments of the disclosure. In some embodiments of the disclosure, the reset signal RESET is a unipolar signal, in which a voltage VM of a same polarity is applied to the mirror 104 in response to the unipolar reset signal. Moreover, the reset signal RESET may have an periodic voltage. However, in other embodiments, the reset signal RESET may also be a bipolar signal, in which a negative voltage VM may be temporarily applied to the mirror 104 in response to the bipolar signal.

In the present embodiment, the controller 112 may derive the states ES1 and ES2 of the first and second electrodes 106 and 108 from a state of the mirror 104 specified in the state data SD from the memory 110. That is, besides separately storing the states of the mirror 104 and the first and second electrodes 106 and 108, the memory 110 may also store a single state of the mirror 104, such that the electrode states of the first and second electrodes 106 and 108 may be derived from the mirror state. Moreover, in other embodiments of the disclosure, the memory 110 may also directly store the mirror state and the electrode states separately in the memory 110.

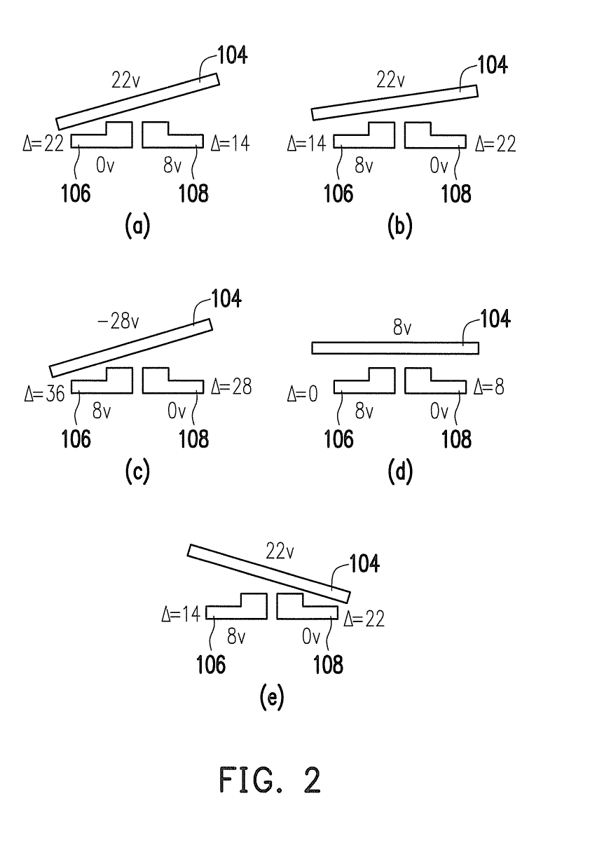

In the disclosure hereafter, several implementations of mirror driving schemes using bipolar and unipolar reset signals are described to better illustrate the operation of the micro-mirror device 100 in the disclosure. It should be noted that FIGS. 2 to 9 accompanying the description hereafter only depict the mirror 104, the first electrode 106, and the second electrode 108 for clarity of the drawings. Moreover, in FIGS. 2 to 9, the voltage shown above the mirror 104 corresponds to the voltage signal VM in FIG. 1, the voltage shown below the first electrode 106 corresponds to the voltage signal VL, and the voltage shown below the second electrode 108 corresponds to the voltage signal VR. Moreover, the delta (A) symbols shown in FIGS. 2 to 9 respectively depict the voltage potential difference between VM and VL (i.e., mirror 104 and first electrode 106), or the voltage potential difference between VM and VR (i.e., mirror 104 and the second electrode 108). In the discussions for FIGS. 2 to 9, the delta values used for discussion are the ones on the left side between the mirror 104 and the first electrode 106, although it should be noted that the delta values on the right side may also be used in other embodiments by analogy. Furthermore, it should be noted that the applied voltage values shown in FIGS. 2 to 9 are for illustrative purposes only. In other embodiments of the disclosure, these values may be adapted to suit a particular application as needed.

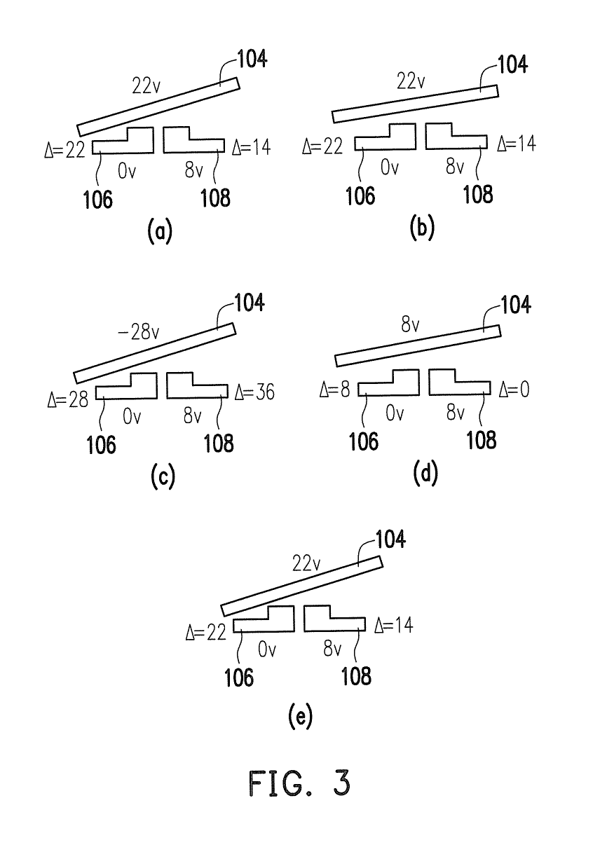

FIGS. 2 and 3 respectively illustrate a bipolar crossover operation and a bipolar stay operation of a micro-mirror device according to an embodiment of the disclosure. In a display apparatus (not drawn) using the micro-mirror 100, for example, the states of the mirror 104 are updated frequently for image projection. The mirror 104 may have its states changed from one state to another, e.g., in a crossover operation, and the mirror 104 may also have its states remain in the same state, e.g., in a stay operation. With reference to the bipolar crossover operation shown in FIG. 2a to FIG. 2e, the first electrode 106 initially has a voltage of 0V (corresponding to a low state), the second electrode 108 initially has a voltage of 8V (corresponding to a high state), and the mirror 104 has a voltage of 22V, as shown in FIG. 2a. The voltage potential difference is 22V between the mirror 104 and the first electrode 106 (i.e., 22V minus 0V), and 14V between the mirror 104 and the second electrode 108 (i.e., 22V minus 8V). Since the first electrode 106 has a higher voltage difference, the mirror 104 is tilted left toward the first electrode 106. When the state of the mirror 104 needs to be changed, such as in a crossover operation, new values for the states of the first and second electrodes 106 and 108 are loaded from memory 110 (e.g. SD in FIG. 1), and voltages (VL and VR) corresponding to the new states (e.g. ES1 and ES2) are applied to the respective electrodes. As shown in FIG. 2b, the states of the first and second electrodes 106 and 108 are changed, in which 8V is applied to the first electrode 106, and 0V is applied to the second electrode 108. As shown in FIG. 2c, to facilitate release of the mirror 104, a reset signal (e.g. RESET) may be used in the micro-mirror device 100 to change the voltage VM applied to the mirror 104. In FIG. 2c, a negative voltage of −28V may be temporarily applied to the mirror 104, which energizes the voltage potential difference from 14V to 36V, thereby increasing the downward electrostatic force that the mirror 104 exerts on the left side. When the reset signal ends, and −28V is no longer applied to the mirror 104, a spring or other suitable elastic material (not drawn) on the left side would exert a force on the mirror 104 corresponding to the force the mirror 104 exerted on the spring. The force from the spring on the left side would cause the mirror 104 to release, as shown in FIG. 2d. After the mirror 104 is released and lifted off the spring, the mirror 104 is tilted to the right side, as shown in FIG. 2e. During the bipolar stay operation depicted in FIGS. 3a-3e, the states of the first and second electrodes 106 and 108 are not changed, and the −28V applied to the minor 104 in FIG. 3c causes less downward electrostatic force than the force generated during the bipolar crossover operation (e.g., Δ=36 in FIG. 2C, Δ=28 in FIG. 3c). The difference in forces exerted during the bipolar crossover and the stay operation allows the mirror 104 to move in the correct position after the reset has been completed.

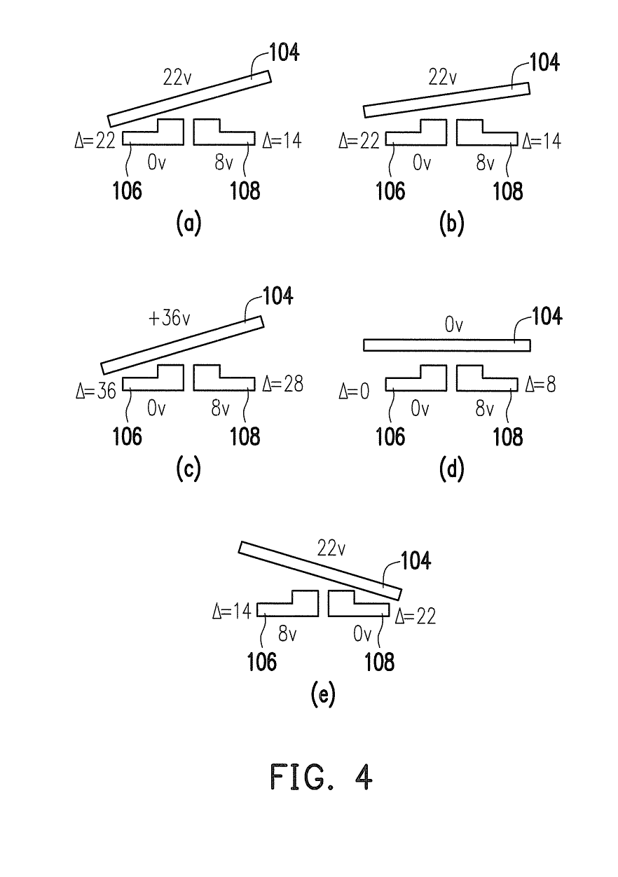

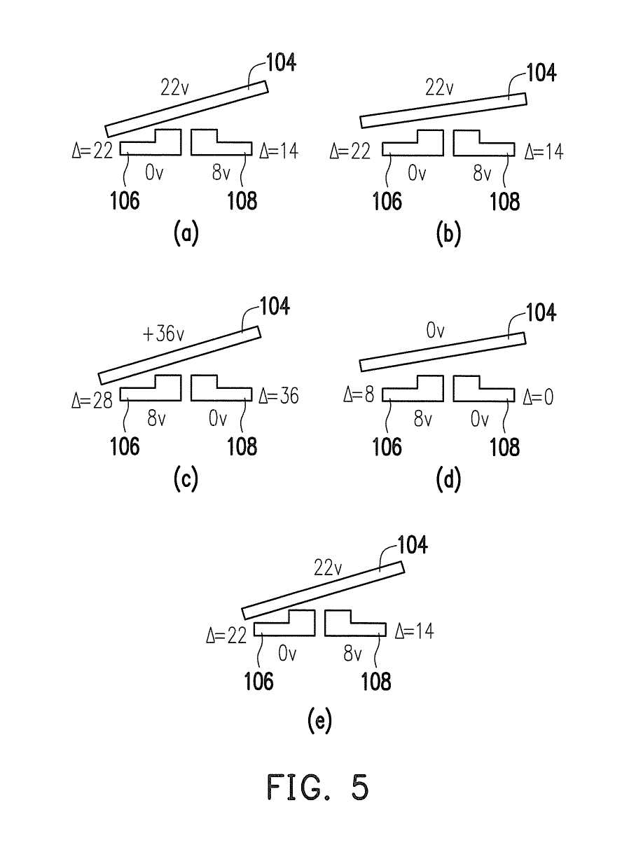

However, the negative voltages used during the bipolar crossover and stay operations may not be suitable for some applications using the micro-minor device 100. An alternative technique is shown in FIGS. 4 and 5, which respectively illustrate a unipolar crossover operation and a unipolar stay operation of a micro-minor device according to an embodiment of the disclosure. With reference to FIGS. 4 and 5, a difference between the bipolar crossover and stay operations depicted in FIGS. 3 and 4 and the unipolar crossover and stay operations depicted in FIGS. 4 and 5 is that, a positive voltage VM (e.g. 36V) is applied to the minor 104 during crossover reset, as shown in FIG. 4c. Due to the positive voltage applied to the mirror 104 during reset, the first electrode 106 is required to be at 0V in FIG. 4b and FIG. 4c. Compared to the bipolar crossover operation in FIG. 2, the voltage potential difference between the mirror 104 and the first electrode 106 in FIG. 4b is Δ=22V, and this results in a smaller force from mirror pre-release in FIG. 4b and crossover reset in FIG. 4c (e.g., Δ=22V to Δ=36V). It should be noted that, in the unipolar crossover operation shown in FIG. 4, the reset energy is a result of the voltage difference 36V during reset between the mirror 104 and first electrode 106 in FIG. 4c minus the voltage difference 22V between the minor 104 and first electrode 106 before the reset in FIG. 4b. In comparison to bipolar crossover of FIG. 2, where the reset energy is a result of the voltage difference 36V between minor 104 and first electrode 106 during the reset in FIG. 2c minus the voltage difference 14V between the minor 104 and first electrode 106 before the reset in FIG. 2b. The effectiveness of reset increases with the increase in the change in the voltage difference between the minor and first electrode during reset compared to just before the reset. Since the voltage difference for bipolar crossover is larger than unipolar crossover, the bipolar reset will be more energetic than unipolar reset. On the other hand, in the unipolar stay operation shown in FIGS. 5a-5e, the positive voltage VM (e.g. 36V) applied to the minor 104 in FIG. 5c results in the same voltage variation between the minor 104 and the first electrode 106 from FIGS. 5b-5c (e.g., Δ=22V to Δ=28V) compared to the bipolar stay operation of FIG. 3.

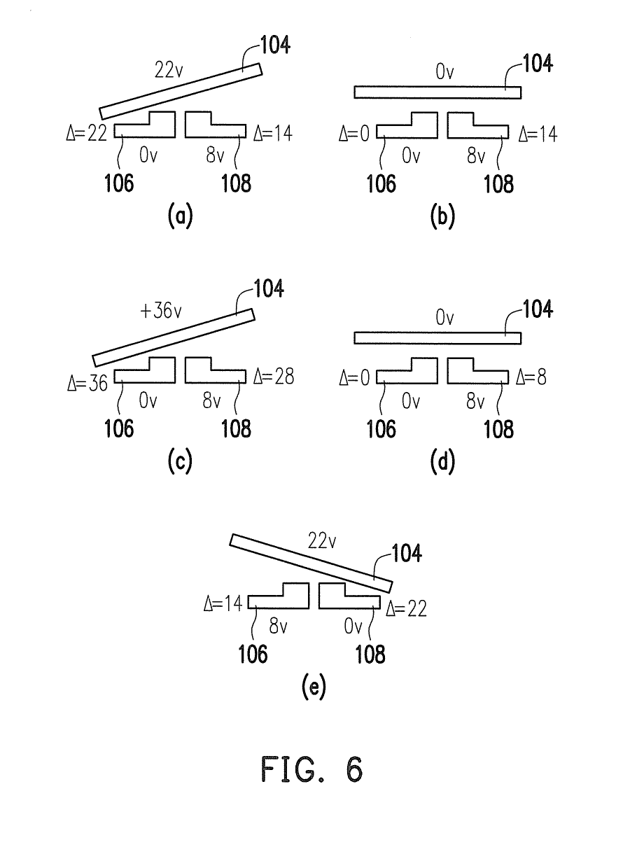

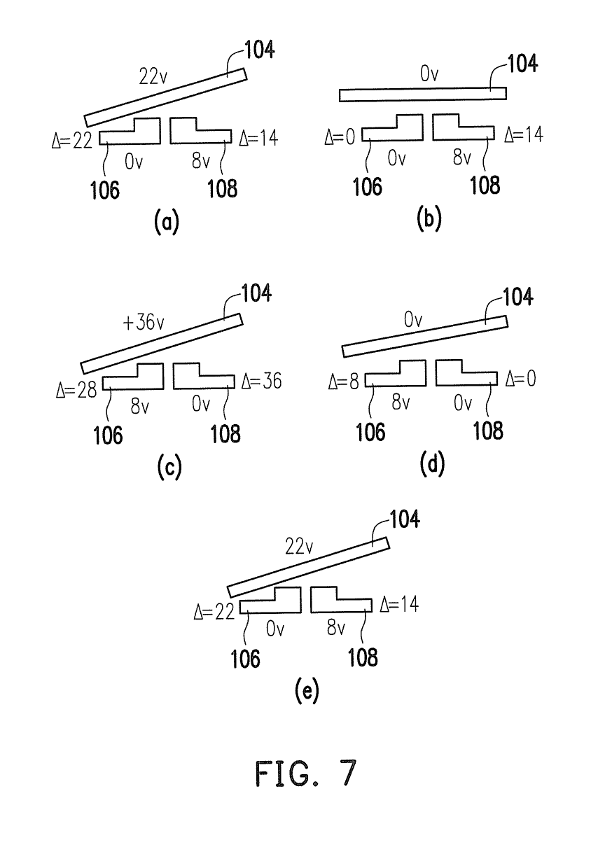

Another technique using unipolar voltage is shown in FIGS. 6 and 7, which respectively illustrate a unipolar crossover operation and a unipolar stay operation with 0V pre-release of a micro-minor device according to an embodiment of the disclosure. As shown in FIG. 6b, before crossover reset in FIG. 6c, a voltage VM of 0V is applied to the minor 104. Since the mirror 104 has 0V in this stage, the minor 104 is able to lift off more than the bipolar crossover operation shown in FIG. 2 and the unipolar crossover operation without 0V pre-release shown in FIG. 4. As shown in FIGS. 6b-6c, the unipolar crossover is energized by voltage change from 0V to 36V (e.g., Δ=0V to Δ=36V), resulting in a larger force from minor pre-release to reset than the bipolar and unipolar crossover operations shown in FIG. 2 and FIG. 4. Accordingly, the minor 104 is shown to lift off in FIG. 6d and tilt to the right side in FIG. 6e. In the unipolar stay operation with 0V pre-release shown in FIGS. 7a-7e, however, the 0V applied to the minor 104 in FIG. 7b causes the minor to lift off more than the bipolar stay operation depicted in FIG. 3. As shown in FIGS. 7b-7c, the voltage change from 0V to 28V causes the mirror to be disturbed more than bipolar stay operation in FIG. 3 (e.g. Δ=22V to Δ=28V), and as a result the mirror 104 cannot stay at the same orientation during the unipolar stay operation with 0V pre-release.

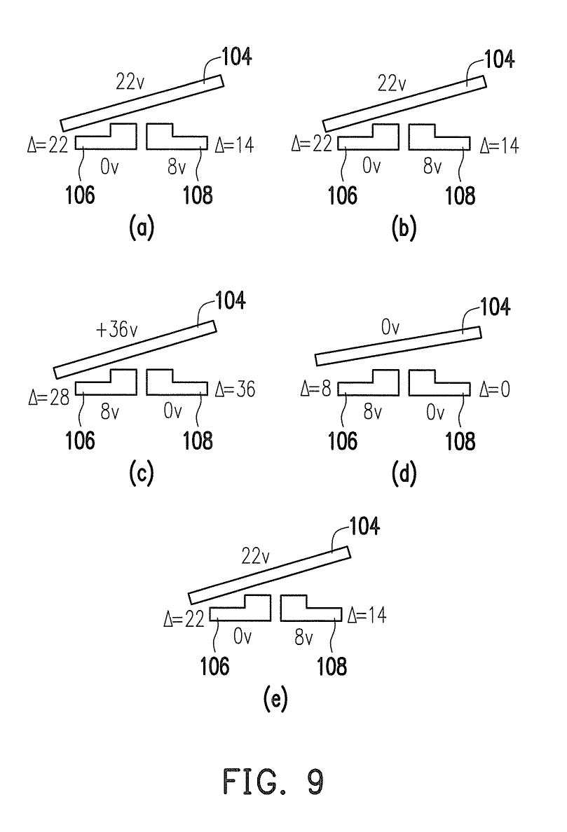

In order to maintain the same reset force as the bipolar crossover operation of FIG. 2 without degradation of the unipolar stay operation with 0V pre-release of FIG. 7, an alternative technique using unipolar voltage is shown in FIGS. 8 and 9, which respectively illustrate a unipolar crossover operation and a unipolar stay operation with electrode state inversion of a micro-minor device according to an embodiment of the disclosure. Compared with the unipolar crossover operation shown in FIG. 4, in the unipolar crossover operation of FIG. 8, the states of the first and second electrodes 106 and 108 are inverted before mirror reset, as shown in FIG. 8b. The state inversion shown in FIG. 8b may be performed by the controller 112 shown in FIG. 1. As shown in FIG. 1 and FIG. 8a, the initial state of the first electrode 106 is 0V, which corresponds to the first electrode state ES1, and the initial state of the second electrode 108 is 8V, which corresponds to the second electrode state ES2 in FIG. 1. The controller 112 may receive the state data SD of the first and second electrodes 106 and 108 from the memory 110. Moreover, in response to the crossover operation request CTRL, the controller 112 inverts the states of the first and second electrodes by applying the second electrode state D2 (e.g. 8V) to the first electrode 106 and applying the first electrode state D1 (e.g. 0V) to the second electrode 108, and the controller 112 sends a reset signal RESET to the mirror 104 according to the modified states of the first and second electrodes 106 and 108. In other words, a electrode state inversion is performed in FIG. 8b before crossover minor reset in FIG. 8c. According to the reset signal RESET, a positive voltage VM of 36V is applied to the minor 104 in FIG. 8c during reset, and the states of the first and second electrodes 106 and 108 are returned to the first electrode state D1 and second electrode state D2 (e.g., 0V and 8V). As a result, the unipolar crossover is energized by the same voltage change from 14V to 36V (e.g., Δ=14V to Δ=36V) as the bipolar crossover operation shown in FIG. 2. In the unipolar stay operation shown in FIGS. 5a-5e, the positive voltage VM (e.g. 36V) applied to the mirror 104 in FIG. 5c results in the same voltage variation between the mirror 104 and the first electrode 106 from FIGS. 5b-5c (e.g., Δ=22V to Δ=28V) compared to the bipolar stay operation of FIG. 3. Accordingly, without using negative voltages as in bipolar operations, the same reset force as the bipolar crossover operation of FIG. 2 is maintained while the same stay performance as the bipolar stay operation is achieved.

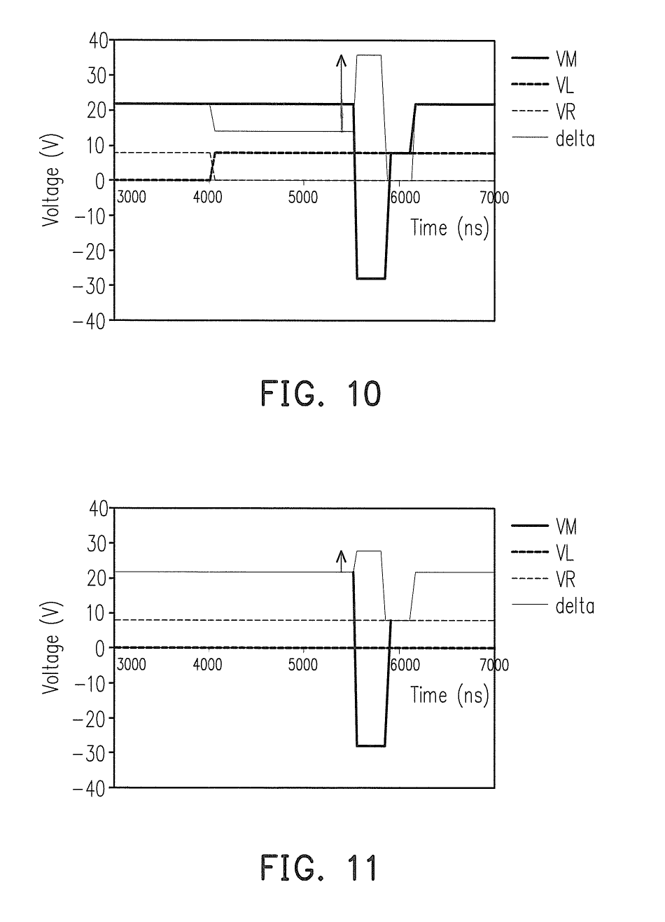

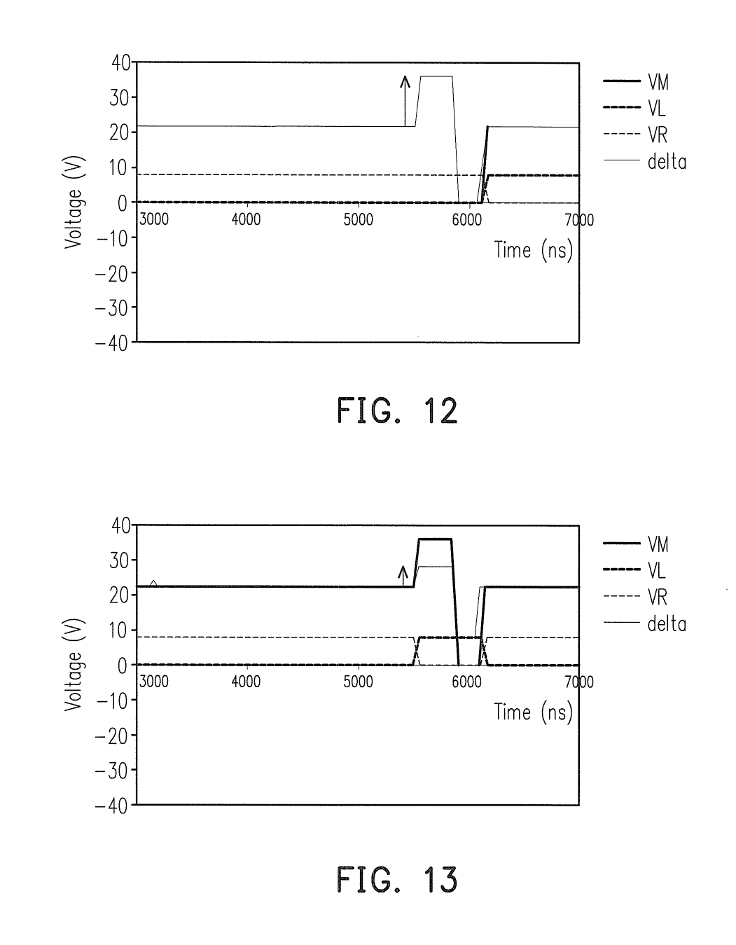

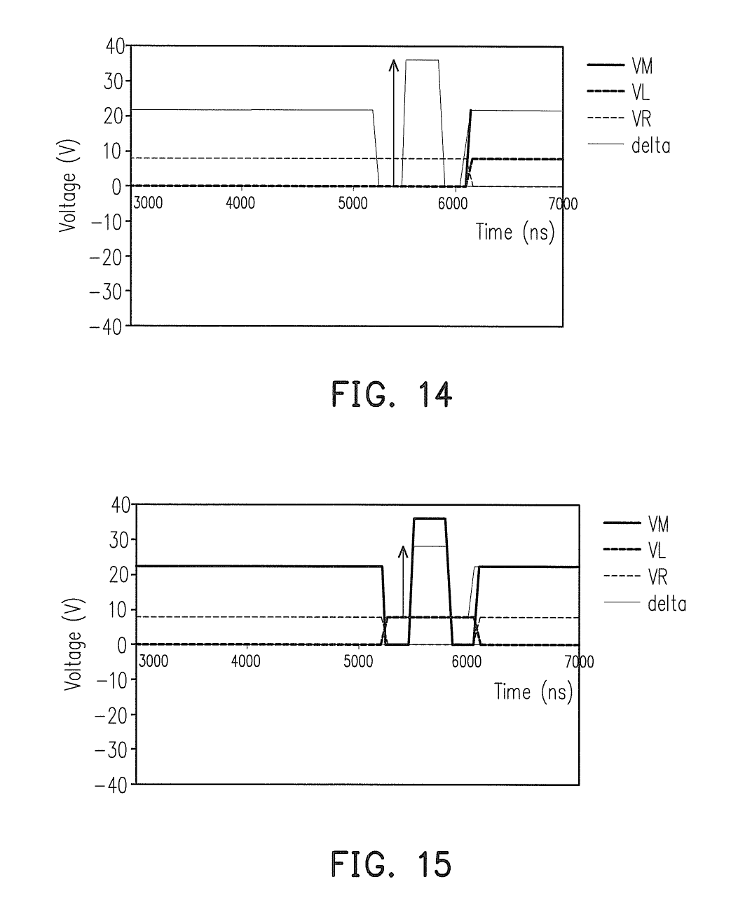

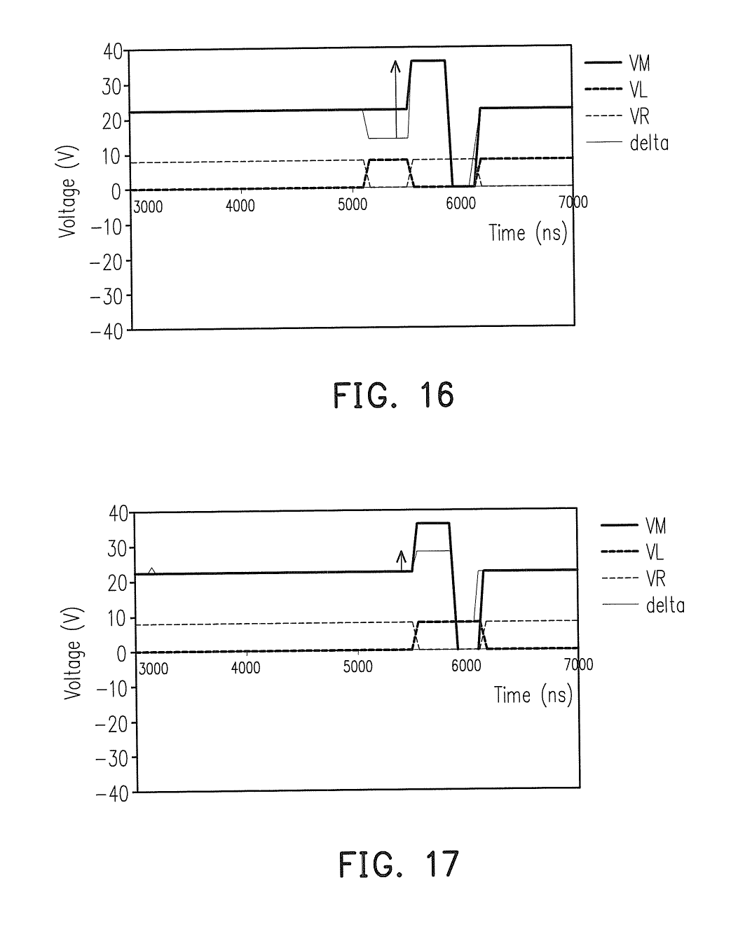

FIGS. 10-17 depict the relationships between voltage and time of the minor driving schemes depicted in FIGS. 2-9. Specifically, FIG. 10 and FIG. 11 respectively illustrate the relationships between voltage and time of the bipolar crossover operation and the bipolar stay operation depicted in FIG. 2 and FIG. 3. FIG. 12 and FIG. 13 respectively illustrate the relationships between voltage and time of the unipolar crossover operation and the unipolar stay operation depicted in FIG. 4 and FIG. 5. FIG. 14 and FIG. 15 respectively illustrate the relationships between voltage and time of the unipolar crossover operation and the unipolar stay operation with 0V pre-release depicted in FIG. 6 and FIG. 7. FIG. 16 and FIG. 17 respectively illustrate the relationships between voltage and time of the unipolar crossover operation and the unipolar stay operation with electrode state inversion depicted in FIG. 8 and FIG. 9. In FIGS. 10-17, a heavy line represents the voltage VM applied to the minor 104, a heavy dotted line represents the voltage VL applied to the first electrode 106, a light dotted light represents the voltage VR applied to the second electrode 108, and a light line represents delta, or the voltage potential difference between the mirror 104 and the first electrode 106. Moreover, a standing upward arrow represents the voltage change for the reset 104.

With reference to FIGS. 10-13, since the unipolar crossover operation has less voltage change at the leading reset edge in FIG. 12, the unipolar crossover operation shown in FIG. 12 has a smaller reset force (shorter upward arrow) than the bipolar crossover operation shown in FIG. 10. However, the unipolar stay operation shown in FIG. 13 has the same stay operation voltage change as the bipolar stay operation shown in FIG. 11. With reference to FIGS. 10-11 and FIGS. 14-15, since the unipolar crossover operation with 0V pre-release has a larger voltage change at the leading reset edge in FIG. 14, the unipolar crossover operation with 0V shown in FIG. 14 has a greater reset force (longer upward arrow) compared to the bipolar crossover operation shown in FIG. 10. However, as shown in FIG. 15, the unipolar stay operation with 0V pre-release of FIG. 15 has more mirror disturbance when compared to the bipolar stay operation shown in FIG. 11, which causes degradation in mirror release.

On the other hand, with reference to FIGS. 10-11 and FIGS. 16-17, since the unipolar crossover operation shown in FIG. 16 inverts the states of the first and second electrodes 106 and 108 before mirror reset, the unipolar crossover operation with electrode state inversion of FIG. 16 has the same reset force (same upward arrow length) as the bipolar crossover operation shown in FIG. 10. Moreover, the unipolar stay operation with electrode state inversion of FIG. 17 also has the same stay operation voltage change as the bipolar stay operation shown in FIG. 11. In other words, due to the unipolar electrode state inversion before mirror reset, the unipolar crossover and stay operations with electrode state inversion are able to maintain the same crossover reset and stay voltage changes as the bipolar crossover and stay operations.

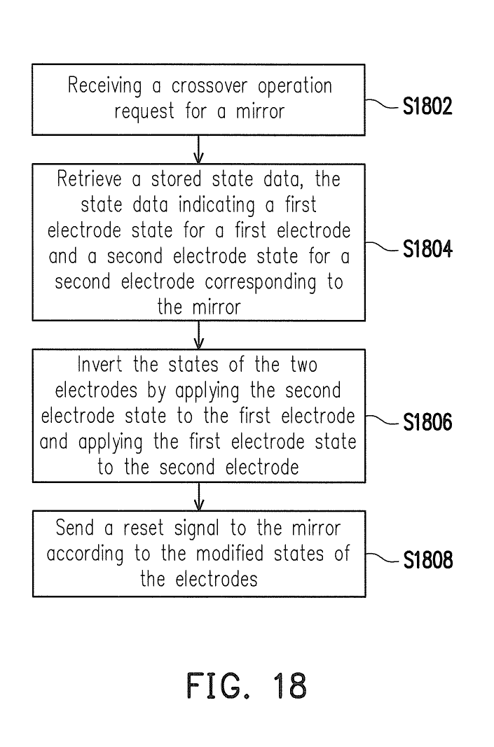

In view of the foregoing disclosure with regards to the micro-mirror device 100 and its driving schemes, a method for driving a mirror in a micro-mirror device may be described using the micro-minor device 100. It should be noted that method disclosed may be implemented in a computer program executed by the controller 112 or an external device, which may be any type of computing device with a suitable processor. FIG. 18 is a flow diagram of a method for driving a mirror in a micro-mirror device according to an embodiment of the disclosure. With reference to FIG. 18, according to the present embodiment, a crossover operation request for a mirror is received in Step S1802. In Step S1804, a stored state data is retrieved in response to the crossover operation request, in which the state data indicates a first electrode state for a first electrode and a second electrode state for a second electrode corresponding to the mirror. In Step S1806, the states of the two electrodes are inverted by applying the second electrode state to the first electrode and applying the first electrode state to the second electrode. In Step S1808, a reset signal is sent to the minor according to the modified states of the electrodes. In some embodiments, the first electrode state is a low state and the second electrode state is a high state. In other embodiments, the first electrode state is a high state and the second electrode state is a low state. In some embodiments, the states of the first and second electrodes are derived from a state of the mirror specified in the state data from the memory. In other embodiments, a reset signal generator provides the reset signal during a reset of the mirror. In some embodiments, the reset signal is a unipolar signal. In other embodiments, the reset signal has a periodic voltage.

In summary, embodiments of the disclosure provide micro-mirror devices and methods of driving a minor thereof By employing unipolar electrode state inversion before mirror reset, the unipolar crossover and stay operations with electrode state inversion are able to maintain the same crossover reset and stay voltage changes as the bipolar crossover and stay operations. Accordingly, negative drive voltages are not required while mirror release degradation in stay operations can be reduced.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

1. A micro-minor device, comprising:
a mirror tiltable about a hinge;
a first electrode and a second electrode disposed on different sides of the hinge;
a memory storing a state data indicating a first electrode state for the first electrode and a second electrode state for the second electrode corresponding to the mirror;
a controller receiving the state data of the first and second electrodes from the memory, and in response to a crossover operation request, the controller inverts states of the first and second electrodes by applying the second electrode state to the first electrode and applying the first electrode state to the second electrode, and the controller sends a reset signal to the minor according to the inverted states of the first and second electrodes, and then the controller returns the states of the first electrode and the second electrode to the first electrode state and the second electrode state.

2. The micro-mirror device according to claim 1, wherein the first electrode state corresponds to a first voltage, and the second electrode state corresponds to a second voltage, the second voltage is larger than the first voltage.

3. The micro-mirror device according to claim 1, wherein the first electrode state corresponds to a second voltage, and the second electrode state corresponds to a first voltage, the second voltage is larger than the first voltage.

4. The micro-mirror device according to claim 1, wherein the controller derives the states of the first and second electrodes from a state of the mirror specified in the state data from the memory.

5. The micro-mirror device according to claim 1, the controller further comprising a reset signal generator providing the reset signal during a reset of the mirror.

6. The micro-mirror device according to claim 1, wherein the reset signal is a unipolar signal.

7. The micro-mirror device according to claim 1, wherein the reset signal has a periodic voltage.

8. The micro-mirror device according to claim 1, further comprising a first amplifier coupled between the first electrode and the controller, and a second amplifier coupled between the second electrode and the controller, the first and second amplifiers being respectively configured to provide power to the first and second electrodes according to the states of the first and second electrodes.

9. The micro-mirror device according to claim 1, wherein the micro-mirror device is a microelectromechanical system (MEMS) device.

10. The micro-mirror device according to claim 1, wherein the first electrode state is zero volt, and the second electrode state is eight volt.

11. The micro-mirror device according to claim 1, wherein the first electrode state is eight volt, and the second electrode state is zero volt.

12. A method for driving a mirror in a micro-mirror device, the method comprising:
receiving a crossover operation request for a mirror;
retrieving a stored state data in response to the crossover operation request, the state data indicating a first electrode state for a first electrode and a second electrode state for a second electrode corresponding to the mirror;
inverting states of the two electrodes by applying the second electrode state to the first electrode and applying the first electrode state to the second electrode; sending a reset signal to the mirror according to the inverted states of the electrodes; and
returning the states of the first electrode and the second electrode to the first electrode state and the second electrode state after the reset signal is sent to the mirror.

13. The method according to claim 12, wherein the first electrode state corresponds to a first voltage, and the second electrode state corresponds to a second voltage, the second voltage is larger than the first voltage.

14. The method according to claim 12, wherein the first electrode state corresponds to a second voltage, and the second electrode state corresponds to a first voltage, the second voltage is larger than the first voltage.

15. The method according to claim 12, wherein the states of the first and second electrodes are derived from a state of the mirror specified in the state data from a memory.

16. The method according to claim 12, wherein a reset signal generator provides the reset signal during a reset of the mirror.

17. The method according to claim 12, wherein the reset signal is a unipolar signal.

18. The method according to claim 12, wherein the reset signal has a periodic voltage.

19. The method according to claim 12, wherein the first electrode state is zero volt, and the second electrode state is eight volt.

20. The method according to claim 12, wherein the first electrode state is eight volt, and the first electrode state is zero volt.
